(19) United States
(12) Patent Application Publication
(10) Pub. No.: US 2005/0181553 A1
(43) Pub. Date: Aug. 18, 2005

(54) Method and apparatus for crystallizing silicon, method of forming a thin film transistor, a thin film transistor and a display apparatus using same

(75) Inventors: Dong-Byum Kim, Seoul (KR); Se-Jin Chung, Yongin-si (KR); Ui-Jin Chung, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 10/844,998

(22) Filed: May 13, 2004

(30) Foreign Application Priority Data
Feb. 13, 2004 (KR) 2004-9533

(51) Int. Cl. H01L 29/04

(52) U.S. Cl. 438/166

(57) ABSTRACT

A light having a pulse frequency higher than about 300 Hz is generated. The light is irradiated on an amorphous silicon thin film for a predetermined time period to form an initial polysilicon crystal. The light is transported in a predetermined direction to grow the initial polysilicon crystal. A laser beam having a decreased output energy is irradiated on the amorphous silicon thin film to crystallize the amorphous silicon thin film to a polysilicon thin film so that the load of an apparatus for generating the laser beam is decreased, and the lifetime of the apparatus for generating the laser beam increases.

### BACKGROUND OF THE INVENTION

1. Technical Field

The present disclosure relates to a method of crystallizing silicon, an apparatus for crystallizing silicon, a method of forming a thin film transistor using the method of crystallizing silicon, a thin film transistor and a display apparatus using same.

2. Discussion of the Related Art

Display apparatuses that convert data in the form of an electric signal to an image are known. The data may be generated from an information processing device such as a computer.

Display apparatuses, include, for example, cathode ray tube (CRT) display apparatuses or flat display apparatuses.

Flat display apparatuses include, for example, liquid crystal display (LCD) apparatuses, plasma display panel (PDP) display apparatuses, and organic electro luminescent display (OELD) apparatuses.

A flat display apparatus includes a thin film transistor to display an image.

The thin film transistor includes a channel layer, a gate electrode, a source electrode and a drain electrode. The channel layer includes, for example, amorphous silicon or polysilicon. When a voltage is applied to the gate electrode, electric current may flow through the channel layer. The source electrode is electrically connected to the channel layer. The drain electrode is electrically connected to the source electrode, and spaced apart from the source electrode.

Amorphous silicon included in a channel layer of a thin film transistor of a display apparatus may be deposited on a substrate at a low temperature.

The substrate having the channel layer may include a glass substrate. Polysilicon may not be formed on the glass substrate, because the polysilicon is formed at a temperature higher than a melting point of the glass substrate.

The electrical characteristics of the channel layer having polysilicon, however, are better than the electrical characteristics of a channel layer having the amorphous silicon. Therefore, display quality of the display apparatus having the amorphous silicon thin film transistor may be deteriorated.

Polysilicon thin film may be formed by an irradiation of light such as a laser beam. When a laser beam is irradiated on the amorphous silicon thin film deposited on the substrate, the amorphous silicon thin film may be melted and crystallized to form polysilicon thin film.

A pulse frequency of a conventional laser beam is low. When the pulse frequency of the laser beam is low, high output energy is necessary for the laser to melt the amorphous silicon. When the output energy of the laser is high, the lifetime of the laser may be decreased.

### SUMMARY OF THE INVENTION

In accordance with an embodiment of the present invention, a method of crystallizing silicon, comprises generating light having a pulse frequency higher than about 300 Hz, irradiating the light on at least one amorphous silicon thin film for a predetermined time period to form an initial polysilicon crystal, and transporting the light in a predetermined direction to grow the initial polysilicon crystal.

The pulse frequency may be in the range of about 300 Hz to about 4 KHz or higher than about 4 KHz. The light may have a rectangular shape. The step of transporting the light may occur continuously or intermittently. The method may further comprise adjusting the velocity of transportation when the light is continuously transported. An interval of transportation of the light may be about 1 μm to about 10 μm when the light is intermittently transported. The light may have an output energy in the range of about 100 mJ to about 1 J.

A method of crystallizing silicon, in accordance with another embodiment of the present invention, comprises generating light having a pulse frequency higher than about 300 Hz, dividing the light into a plurality of light portions, irradiating each of the plurality of light portions on a respective amorphous silicon thin film of a plurality of amorphous silicon thin films for a predetermined time period to form a plurality of initial polysilicon crystals, and transporting each of the plurality of light portions in a predetermined direction to grow the plurality of initial polysilicon crystals.

An apparatus for crystallizing silicon in accordance with an embodiment of the present invention, comprises a light source for generating a primary beam having a pulse frequency higher than about 300 Hz, an attenuator positioned adjacent to the light source for generating an attenuated beam, a concentrator positioned adjacent to the attenuator for concentrating the attenuated beam, and a light shape transformer positioned adjacent to the concentrator for transforming a shape of the concentrated beam and for generating a transformed beam, wherein the transformed beam is irradiated on an amorphous silicon thin film to form a polysilicon thin film.

The pulse frequency may be in the range of about 300 Hz to about 4 KHz or higher than about 4 KHz. The apparatus may further comprise a transporting unit for transporting one of the amorphous silicon thin film or the light shape transformer so that the transformed beam is transported along the amorphous silicon thin film to grow polysilicon crystal. The apparatus may further include a mirror for changing a direction of the attenuated beam and a mirror for changing a direction of the concentrated beam. A cross-section of each of the primary beam, the attenuated beam and the concentrated beam may be a circular shape. The shape of the concentrated beam may be transformed into an elliptical shape or a rectangular shape. A cross-sectional length of the concentrated beam is not be less than about 700 mm and the cross-sectional width of the concentrated beam is not more than about 5 μm.

An apparatus for crystallizing silicon, in accordance with another embodiment of the present invention, comprises a light source for generating a primary beam having a pulse frequency higher than about 300 Hz, an attenuator positioned adjacent to the light source for generating an attenuated beam, a concentrator positioned adjacent to the attenuator for concentrating the attenuated beam and generating a concentrated beam, a beam divider positioned adjacent to the concentrator for dividing the concentrated beam into at least two beams, and at least two light shape transformers positioned adjacent to the beam divider for respectively transforming a shape of each of the at least two beams and generating at least two respective transformed beams, wherein the at least two respective transformed beams are respectively irradiated on at least two amorphous silicon thin films to form at least two polysilicon thin films.

A method of forming a thin film transistor, in accordance with another embodiment of the present invention, comprises forming a gate electrode on a substrate, forming a first insulating layer on the substrate having the gate electrode formed thereon, forming an amorphous silicon thin film is formed on the first insulating layer, irradiating light having a pulse frequency in the range of about 300 Hz to about 4 kHz on the amorphous silicon thin film, transporting the light in a predetermined direction to grow polysilicon crystals to form a polysilicon thin film, and patterning the polysilicon thin film i to form a polysilicon layer on the first insulating layer.

The method may further comprise forming a second insulating layer on the first insulating layer, wherein the second insulating layer includes a first contact hole and a second contact hole exposing the polysilicon layer. The first and second contact holes may be spaced apart from each other. A source electrode and a drain electrode may be formed on the second insulating layer corresponding to the first and second contact holes. The source electrode may be electrically connected to the polysilicon pattern through the first contact hole. The drain electrode may be electrically connected to the polysilicon pattern through the second contact hole.

A thin film transistor, in accordance with an embodiment of the present invention, comprises a gate electrode formed on a substrate, a first insulating layer formed on the substrate including the gate electrode formed thereon, and a channel layer disposed on the first insulating layer, wherein the channel layer includes a plurality of polysilicon crystals arranged in a predetermined crystal growth direction.

A second insulating layer may be disposed on the channel layer, and may include a first contact hole and a second contact hole. A source electrode and a drain electrode may be formed on the second insulating layer, wherein the source electrode is electrically connected to the channel layer through the first contact hole, and the drain electrode is electrically connected to the channel layer through the second contact hole. The plurality of polysilicon crystals may be parallelly disposed with respect to each other. The predetermined crystal growth direction may be substantially parallel to a transporting direction of a laser beam for forming the plurality of polysilicon crystals. The laser beam may have a pulse frequency in the range of about 300 Hz to about 4 KHz. A liquid crystal display apparatus may include the thin film transistor.

A display apparatus, in accordance with another embodiment of the present invention, comprises a first substrateincluding a thin film transistor and a pixel electrode, a second substrate including a common electrode, wherein a liquid crystal layer is capable of being interposed between the first and second substrates, and the thin film transistor includes a gate electrode formed on a transparent substrate, a first insulating layer formed on the transparent substrate including the gate electrode formed thereon, and a channel layer disposed on the first insulating layer, wherein the channel layer includes a plurality of polysilicon crystals arranged in a predetermined crystal growth direction. The amorphous silicon is crystallized to form the polysilicon. The polysilicon may also be crystallized to form single crystalline silicon.

A laser beam having the decreased output energy is irradiated on the amorphous silicon thin film to crystallize the amorphous silicon thin film to a polysilicon thin film so that the load of the apparatus of generating the laser beam is decreased, and the lifetime of the apparatus for generating the laser beam increases. In addition, the characteristics of the thin film transistor and the display quality of the display apparatus is improved.

### BRIEF DESCRIPTION OF THE DRAWINGS

Preferred embodiments of the invention can be understood in more detail from the following descriptions taken in conjunction with the accompanying drawings in which:

FIG. 1 is a flow chart showing a method of crystallizing silicon in accordance with an embodiment of the present invention;

FIG. 2 is a cross-sectional view showing a silicon crystallizing process in accordance with an embodiment of the present invention;

FIG. 3 is a plan view showing a silicon crystallizing process in accordance with an embodiment of the present invention;

FIG. 4 is a flow chart showing a method of crystallizing silicon in accordance with an embodiment of the present invention;

FIG. 5 is a cross-sectional view showing a silicon crystallizing process in accordance with an embodiment of the present invention;

FIG. 6 is a schematic view showing an apparatus for crystallizing silicon in accordance with an embodiment of the present invention;

FIG. 7 is a schematic view showing an apparatus for crystallizing silicon in accordance with an embodiment of the present invention;

FIG. 8 is a graph showing a relationship between a light transmittance and a rotation angle of a beam dividing lens shown in FIG. 7;

FIG. 9 is a cross-sectional view showing a thin film transistor in accordance with an embodiment of the present invention;

FIG. 10 is a plan view showing a polysilicon layer shown in FIG. 9;

FIGS. 11A to 11E are cross sectional views for illustrating a method of forming a thin film transistor in accordance with an embodiment of the present invention; and

FIG. 12 is a cross sectional view showing a display apparatus in accordance with an embodiment of the present invention.

### DETAILED DESCRIPTION OF THE PREFERRED EMBODIMENTS

Preferred embodiments of the present invention will now be described more fully hereinafter below with reference to the accompanying drawings. This invention may, however, be embodied in different forms and should not be construed as limited to the embodiments set forth herein. Rather, these embodiments are provided so that this disclosure will be thorough and complete, and will fully convey the scope of the invention to those skilled in the art.

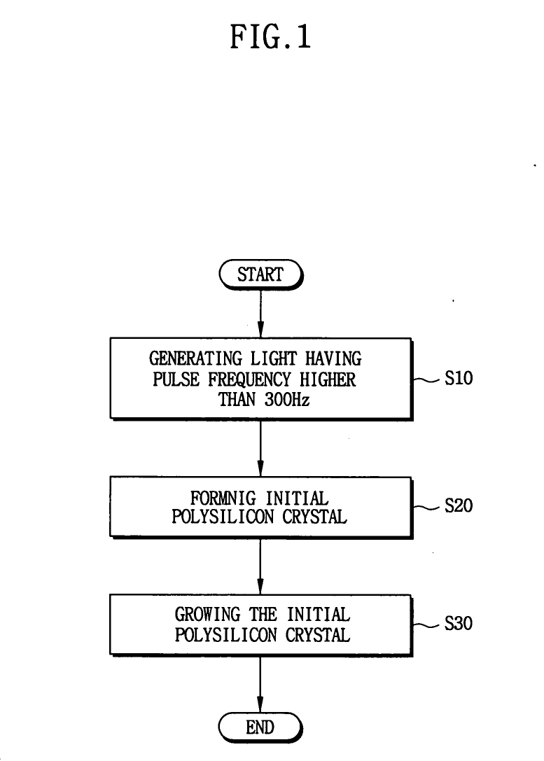

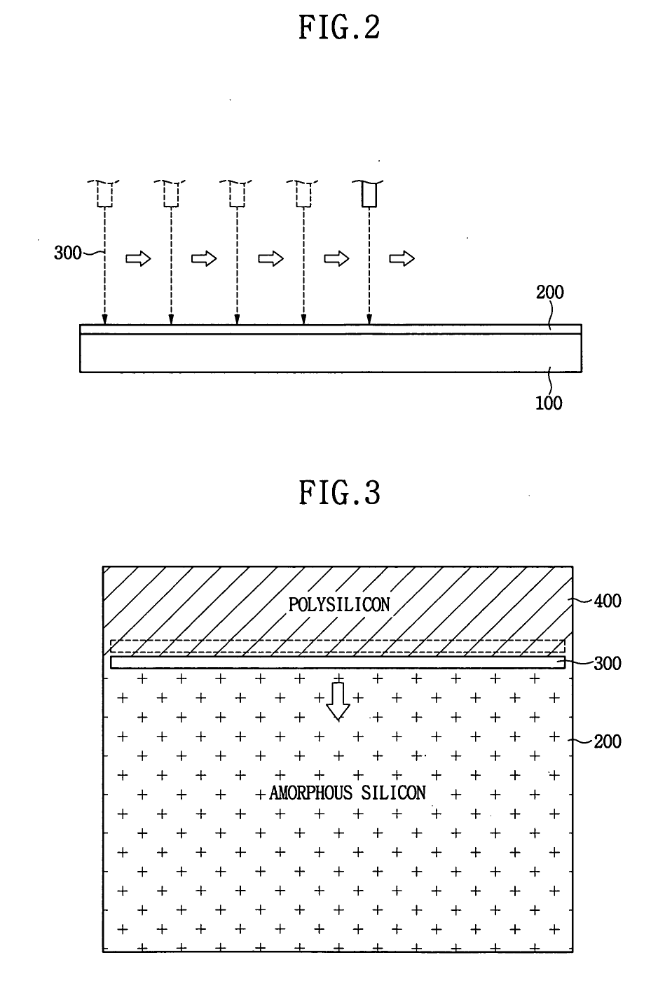

FIG. 1 is a flow chart showing a method of crystallizing silicon in accordance with an embodiment of the present invention. FIG. 2 is a cross-sectional view showing a silicon crystallizing process in accordance with an embodiment of the present invention.

Referring to FIGS. 1 and 2, an amorphous silicon thin film 200 is formed on a substrate 100.

In order to crystallize the amorphous silicon thin film 200 to a polysilicon thin film, light having a pulse frequency higher than about 300 Hz is generated (Step S10). The light may be a laser beam.

If the amorphous silicon thin film 200 was crystallized to the polysilicon thin film using a laser beam having a pulse frequency less than about 300 Hz (“first pulse frequency”), then the output energy would be more than about 1 J (“first output energy”). An output energy at this level may result in a malfunction of a laser beam generating apparatus.

A laser beam having the first pulse frequency and the first output energy would have to be irradiated on the amorphous silicon thin film 200 for a first time period. The laser beam having the first pulse frequency and the first output energy may be intermittently irradiated, or the output energy of the laser beam may also be intermittently changed to form the laser beam having the first pulse frequency.

If the laser beam having the first pulse frequency and the first output energy is irradiated on the amorphous silicon thin film 200 for the first time period, the amorphous silicon in the amorphous silicon thin film 200 may be melted.

It should be noted that the pulse frequency is inversely proportional to the output energy and the output energy increases in proportion to a load of the laser beam generating apparatus. Accordingly, when the pulse frequency decreases, the output energy increases along with a load of the laser beam generating apparatus.

Therefore, the first pulse frequency, which is less than about 300 Hz, results in a higher output energy than would be achieved with a pulse frequency higher than about 300 Hz. As a result, a load of a laser beam generating apparatus is high at a low pulse frequency (due to the higher output energy), and the laser beam generating apparatus may malfunction.

In an embodiment of the present invention, the light includes the laser beam 300 with a pulse frequency higher than about 300 Hz (“second pulse frequency”) resulting in a “second” output energy, which is lower than the first output energy. The second pulse frequency is higher than the first pulse frequency, and the second output energy is about 100 mJ to about 1 J.

The second pulse frequency of the laser beam 300 is about 300 Hz to about 4 kHz. When the pulse frequency of the laser beam is less than about 300 Hz, substitution of a laser tube for oscillation may be required after the laser tube is oscillated less than about 1.2 billion times. Therefore, the manufacturing cost of the display apparatus increases. Preferably, the second pulse frequency of the laser beam 300 is about 2 kHz to about 4 kHz. Alternatively, the second pulse frequency of the laser beam 300 may be higher than about 4 kHz.

The laser beam 300 having the second pulse frequency and the second output energy is irradiated on the amorphous silicon thin film for a second time period. The laser beam has a rectangular shape that extends in a predetermined direction.

The laser beam 300 having the second pulse frequency and the second output energy is irradiated on the amorphous silicon thin film for the second time period to melt the amorphous silicon thin film. The first time period may be different from or substantially equal to the second time period.

When the laser beam 300 having the second pulse frequency and the second output energy is irradiated on the amorphous silicon thin film to melt the amorphous silicon thin film, the load of the apparatus of generating the laser beam 300 is decreased, and the lifetime of the apparatus of generating the laser beam 300 increases.

FIG. 3 is a plan view showing a silicon crystallizing process in accordance with an embodiment of the present invention.

Referring to FIG. 3, the laser beam 300 has the second pulse frequency and the second output energy for melting the amorphous silicon thin film 200. Therefore, an initial polysilicon crystal is formed at a position adjacent to the amorphous silicon thin film 200 (Step S20).

The laser beam 300 having the second pulse frequency and the second output energy is transported along the amorphous silicon thin film 200 to laterally grow the initial polysilicon crystal along the transporting direction of the laser beam 300, thereby forming a polysilicon thin film 400 (Step S30).

The laser beam 300 may be continuously transported, or intermittently transported on the substrate 100. When the laser beam 300 is continuously transported on the substrate 100, the velocity of the transportation can be adjusted to ensure melting of the amorphous silicon thin film 200.

In this embodiment, when the laser beam 300 is intermittently transported, the interval of the transportation of the laser beam 300 is about 1 μm to about 10 μm.

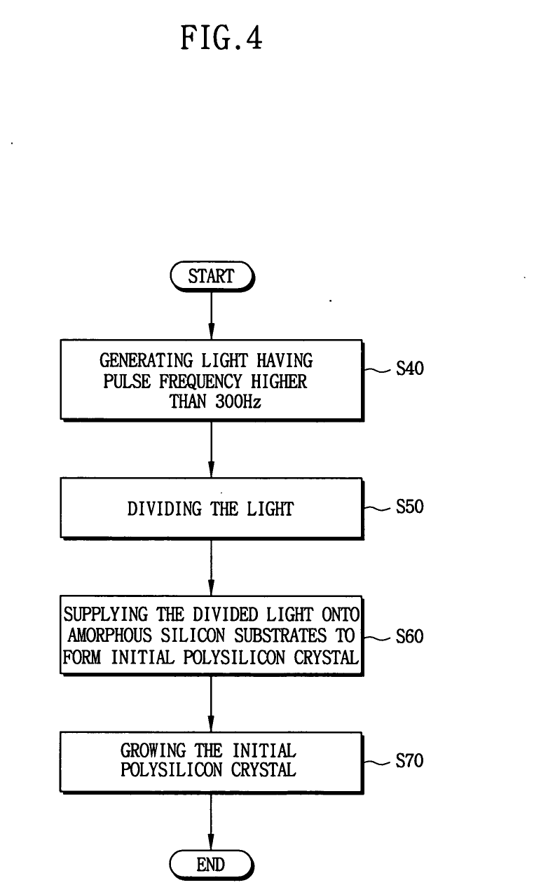

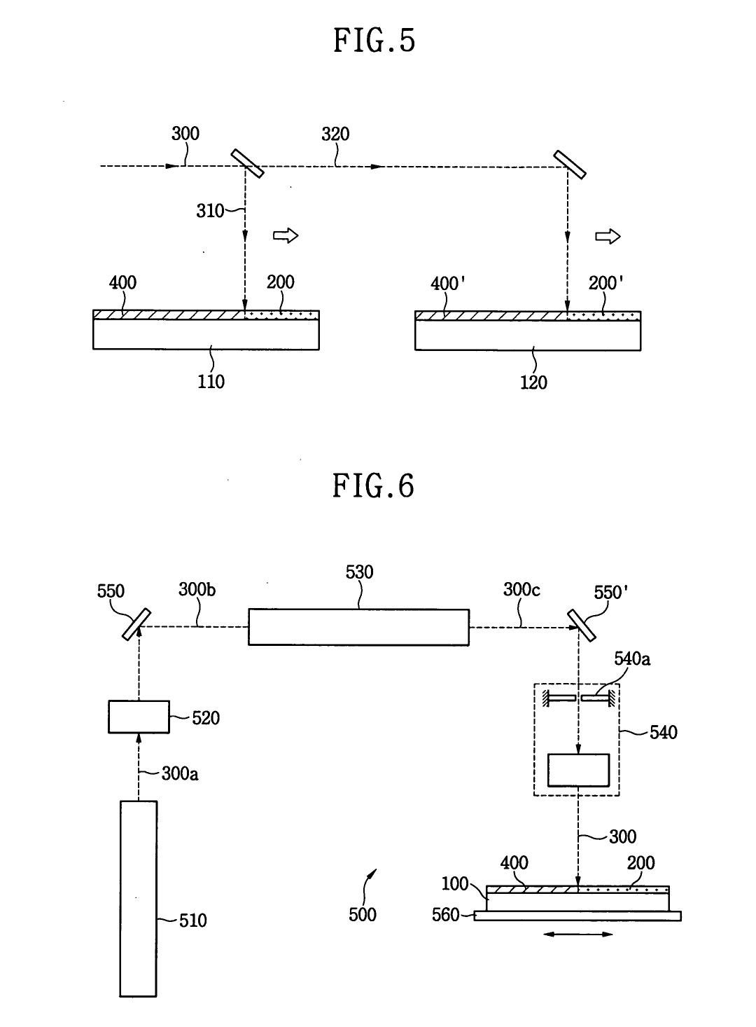

FIG. 4 is a flow chart showing a method of crystallizing silicon in accordance with another embodiment of the present invention. FIG. 5 is a cross-sectional view showing a silicon crystallizing process in accordance with another embodiment of the present invention.

Referring to FIGS. 4 and 5, a plurality of silicon thin films are formed on a plurality of substrates, respectively. In this embodiment, two silicon thin films are formed on two substrates 110 and 120, and the silicon thin films are amorphous silicon thin films 200 and 200′.

To crystallize the amorphous silicon thin films 200 and 200′ to polysilicon thin films 400 and 400′ on each of the substrates 110 and 120, a light having a pulse frequency higher than about 300 Hz is generated (Step S40).

If the amorphous silicon thin films 200 and 200′ were crystallized to the polysilicon thin films 400 and 400′ using the laser beam including a first pulse frequency (less than about 300 Hz) and a corresponding first output energy, the laser beam generating apparatus may malfunction. The laser beam having the first pulse frequency and the first output energy would be irradiated on the amorphous silicon thin films 200 and 200′ for a first time period to melt the amorphous silicon.

Since the pulse frequency is in inverse proportion to the output energy and the output energy increases in proportion to a load of an apparatus for generating the laser beam, the laser beam generating apparatus may malfunction if the pulse frequency is above a predetermined level.

To prevent the malfunction of the laser beam generating apparatus, in an embodiment of the present invention, the laser beam 300 includes a second pulse frequency that is higher than the first pulse frequency and a second output energy that is lower than the first output energy.

The second pulse frequency of the laser beam 300 is about 300 Hz to about 4 kHz. Preferably, the second pulse frequency of the laser beam 300 is about 2 kHz to about 4 kHz. Alternatively, the second pulse frequency of the laser beam 300 may be higher than about 4 kHz. The second output energy is in the range of about 100 mJ to about 1 J.

The laser beam 300 having the second pulse frequency is divided into a plurality of laser beam portions (Step S50). The number of the laser beam portions is equal to the number of the substrates having the amorphous silicon thin films 200 and 200′ formed thereon. In this embodiment, the laser beam 300 having the second pulse frequency is divided into two laser beam portions 310 and 320 using a beam divider. The light transmittance of the laser beam 300 that passes through the beam divider is dependent on the incident angle of the laser beam 300 into the beam divider.

Each of the laser beam portions 310 and 320 has the second pulse frequency and an output energy. The output energy of each of the laser beam portions 310 and 320 is smaller than the first output energy. The output energy of the laser beam 300 (e.g., the second output energy) may be greater than the output energy of each of the laser beam portions 310 and 320.

Each of the laser beam portions 310 and 320 has a rectangular shape that extends in a predetermined direction. Each of the laser beam portions 310 and 320 is respectively irradiated on each of the amorphous silicon thin films 200 and 200′ formed on each of the substrates 110 and 120 for a second time period to melt the amorphous silicon thin films 200 and 200′. The first time period may be different from or substantially equal to the second time period.

When the laser beam portions 310 and 320 having the second pulse frequency and the second output energy are irradiated on the amorphous silicon to melt the amorphous silicon thin films 200 and 200′, the load of the apparatus for generating the laser beam 300 may be decreased, and the lifetime of the laser beam generating apparatus increases.

The laser beam portions 310 and 320 having the second pulse frequency and the second output energy are respectively irradiated on the amorphous silicon thin films 200 and 200′ to melt the amorphous silicon thin films 200 and 200′. Therefore, initial polysilicon crystals are formed at positions adjacent to the amorphous silicon thin films 200 and 200′ (Step S60).

The laser beam portions 310 and 320 having the second pulse frequency and the second output energy are transported along the amorphous silicon thin film 200 and 200′ to laterally grow the initial polysilicon crystals along the transporting direction of the laser beam portions 310 and 320, thereby forming polysilicon thin films 400 and 400′ (Step S70).

The laser beam portions 310 and 320 having the second pulse frequency and the second output energy may be continuously transported, or intermittently transported on the substrates 110 and 120. When the laser beam portions 310 and 320 are continuously transported on the substrates 110 and 120, the velocity of the transportation is adjusted to ensure melting of the amorphous silicon thin films 200 and 200′.

In this embodiment, when the laser beam portions 310 and 320 are intermittently transported, the intervals of the transportation of the laser beam portions 310 and 320 are about 1 μm to about 10 μm.

FIG. 6 is a schematic view showing an apparatus for crystallizing silicon in accordance with an embodiment of the present invention.

Referring to FIG. 6, the apparatus for crystallizing silicon 500 includes a light source 510, an attenuator 520, a concentrator 530, a light shape transformer 540 and a transporting unit 560.

The light source 510 generates a primary laser beam 300a. Preferably, a pulse frequency of the primary laser beam 300a is not less than about 300 Hz.

If the pulse frequency of the primary laser beam 300a were less than about 300 Hz, the output energy of the primary laser beam 300a would be increased enough to melt amorphous silicon. The output energy of the laser beam 300a increases in proportion to a load of the apparatus for generating the laser beam. Therefore, the apparatus for generating the laser beam may malfunction if the pulse frequency is below approximately 300 Hz.

To prevent the malfunction of the laser beam generating apparatus, the pulse frequency of the primary laser beam 300a generated from the light source 510 is not below about 300 Hz. Since the output energy of the primary laser beam 300a decreases in inverse proportion to the pulse frequency, the lifetime of the light source 510 is thereby increased.

The pulse frequency of the primary laser beam 300a is about 300 Hz to about 4 kHz. Alternatively, the pulse frequency of the primary laser beam 300a may be higher than about 4 kHz.

The attenuator 520 is disposed at a position adjacent to the light source 510. The primary laser beam 300a is incident into the attenuator 520. The attenuator 520 accurately controls the output energy of the primary laser beam 300a incident therein to output an attenuated laser beam 300b. The attenuated laser beam 300b is reflected from a mirror 550 so that the direction of the attenuated laser beam 300b can be changed.

The concentrator 530 is disposed at a position adjacent to the attenuator 520. The concentrator 530 concentrates the attenuated laser beam 300b. The concentrator 530 includes a focusing lens or a plurality of focusing lenses. The concentrated laser beam 300c is reflected from a mirror 550′ so that the direction of the concentrated laser beam 300c can be changed.

The light shape transformer 540 is disposed at a position adjacent to the concentrator 530. The light shape transformer 540 transforms a shape of the concentrated laser beam 300c. A cross-section of each of the primary laser beam 300a, the attenuated laser beam 300b and the concentrated laser beam 300c is a circular shape.

The light shape transformer 540 transforms the concentrated laser beam 300c to an elliptical shape or a rectangular shape using a concave lens or a convex lens, respectively. In this embodiment, the light shape transformer 540 transforms the concentrated laser beam 300c to the rectangular shape. By passing through the light shape transformer 540, the shape of the concentrated laser beam 300c is transformed resulting in the laser beam 300, which is irradiated on an amorphous silicon thin film 200. Preferably, the cross sectional length of the concentrated laser beam 300c that passes through the light shape transformer 540 is no less than about 700 mm, and the cross sectional width of the concentrated laser beam 300c is no more than about 5 μm.

The light shape transformer 540 may include a mask 540a for transforming the shape of the concentrated laser beam 300c.

The laser beam 300 outputted from the light shape transformer 540 is irradiated on the amorphous silicon thin film 200 to transform the amorphous silicon thin film 200 to a polysilicon thin film 400.

The transporting unit 560 transports the silicon thin film 200 or the light shape transformer 540 so that the laser beam 300 outputted from the light shape transformer 540 is transported along the amorphous silicon thin film 200 to laterally grow the polysilicon crystal, thereby forming the polysilicon thin film 400.

Transportation may be continuous or intermittent. When the laser beam 300 is continuously transported, the velocity of the transportation can be adjusted to ensure melting of the amorphous silicon thin film 200. When transportation is intermittent, the interval of the transportation of the laser beam 300 is about 1 μm to about 10 μm.

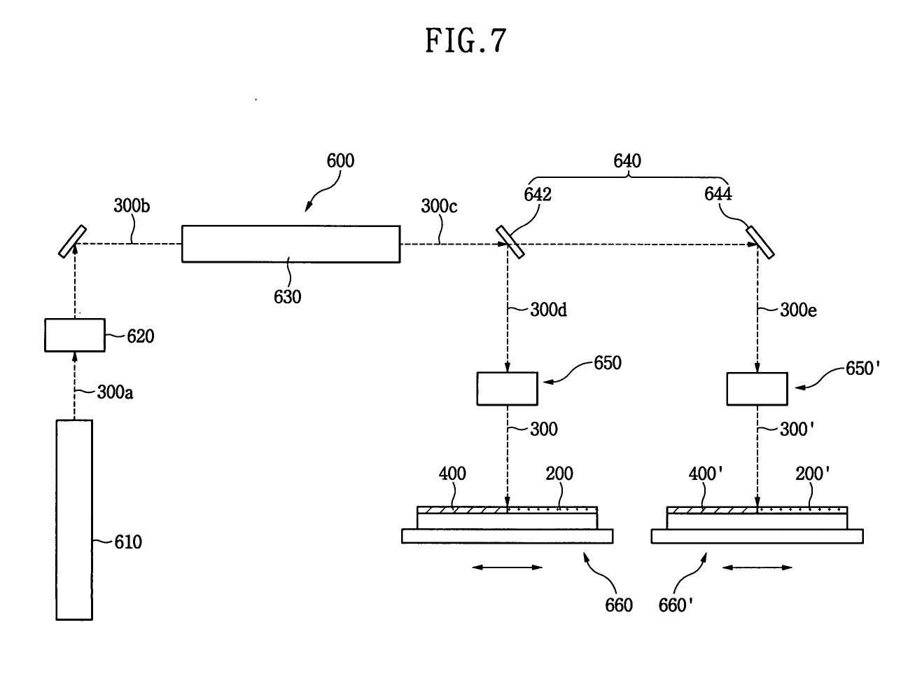

FIG. 7 is a schematic view showing an apparatus for crystallizing silicon in accordance with another embodiment of the present invention.

Referring to FIG. 7, the apparatus for crystallizing silicon 600 includes a light source 610, an attenuator 620, a concentrator 630, a beam divider 640, light shape transformers 650 and 650′ and transporting units 660 and 660′. The apparatus for crystallizing silicon 600 may include more than two light shape transformers and more than two transporting units. In this embodiment, the apparatus for crystallizing silicon 600 includes the two light shape transformers 650 and 650′ and the two transporting units 660 and 660′.

The light source 610 generates a primary laser beam 300a. Preferably, a pulse frequency of the primary laser beam 300a is not less than about 300 Hz.

If the pulse frequency of the primary laser beam 300a were less than about 300 Hz, the output energy of the primary laser beam 300a would be increased enough to melt amorphous silicon. The output energy of the laser beam 300a increases in proportion to a load of the apparatus for generating the laser beam. Therefore, the apparatus for generating the laser beam may malfunction if the pulse frequency is below approximately 300 Hz.

The pulse frequency of the primary laser beam 300a generated from the light source 610 is not below about 300 Hz. Since the output energy of the primary laser beam 300a decreases in inverse proportion to the pulse frequency, the lifetime of the light source 610 is thereby increased.

The pulse frequency of the primary laser beam 300a is about 300 Hz to about 4 kHz. Alternatively, the pulse frequency of the primary laser beam 300a may be higher than about 4 kHz.

The attenuator 620 is disposed at a position adjacent to the light source 610. The primary laser beam 300a is incident into the attenuator 620. The attenuator 620 accurately controls the output energy of the primary laser beam 300a incident therein to output an attenuated laser beam 300b.

The concentrator 630 is disposed at a position adjacent to the attenuator 620. The concentrator 630 concentrates the attenuated laser beam 300b. The concentrator 630 includes a focusing lens. The concentrator 630 may also include a plurality of focusing lenses.

The beam divider 640 is disposed at a position adjacent to the concentrator 630. The beam divider 640 divides the concentrated laser beam 300c into a plurality of laser beam portions. In this embodiment, the beam divider 640 divides the concentrated laser beam 300c into two laser beam portions 300d and 300e, and the beam divider 640 includes two beam dividing lenses 642 and 644. The beam divider 640 may include more than two beam dividing lenses.

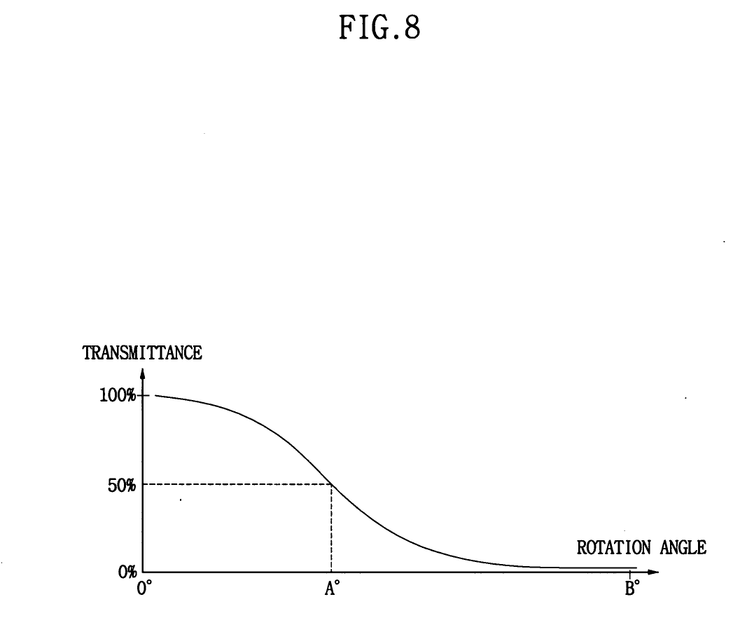

FIG. 8 is a graph showing a relationship between light transmittance and a rotation angle of a beam dividing lens shown in FIG. 7.

Referring to FIG. 8, the horizontal axis represents the rotation angle of each of the beam dividing lenses 642 and 644 and the vertical axis represents the light transmittance of the laser beam that passes through each of the beam dividing lenses 642 and 644.

When each of the beam dividing lenses 642 and 644 is substantially perpendicular to a direction of the concentrated laser beam 300c, the rotation angle of each of the beam dividing lenses 642 and 644 is about 0° so that the light transmittance of each of the beam dividing lenses 642 and 644 is substantially 100%. That is, when the rotation angle of each of the beam dividing lenses 642 and 644 is about 0°, substantially all of the concentrated laser beam 300c passes through each of the beam dividing lenses 642 and 644.

When each of the beam dividing lenses 642 and 644 is inclined at an angle of about 45° with respect to the direction of the concentrated laser beam 300c, the rotation angle of each of the beam dividing lenses 642 and 644 is A° so that the light transmittance of each of the beam dividing lenses 642 and 644 is substantially 50%. That is, when the rotation angle of each of the beam dividing lenses 642 and 644 is A°, about a half of the concentrated laser beam 300c is reflected from each of the beam dividing lenses 642 and 644, and remaining portion of the concentrated laser beam 300c passes through each of the beam dividing lenses 642 and 644.

When each of the beam dividing lenses 642 and 644 is inclined at an angle of about 80° with respect to the direction of the concentrated laser beam 300c, the rotation angle of each of the beam dividing lenses 642 and 644 is B° so that the light transmittance of each of the beam dividing lenses 642 and 644 is about 0%. That is, when the rotation angle of each of the beam dividing lenses 642 and 644 is B°, substantially all of the concentrated laser beam 300c is reflected from each of the beam dividing lenses 642 and 644 and does not pass through the beam dividing lenses 642 and 644.

The concentrated laser beam 300c is divided into the two laser beam portions 300d and 300e. The beam divider 640 may include a plurality beam dividing lenses. The beam dividing lenses may be disposed parallelly, serially, etc. The beam dividing lenses may also be arranged in a matrix shape. In this embodiment, the number of the laser beam portions 300d and 300e is equal to that of the amorphous silicon thin films 200 and 200′.

The output energy of one of the laser beam portions 300d and 300e is smaller than that of the concentrated laser beam 300c.

The light shape transformers 650 and 650′ are disposed between the beam divider 640 and the transporting units 660 and 660′, respectively. Each of the light shape transformers 650 and 650′ transforms a shape of each of the laser beam portions 300d and 300e. Each of the primary laser beam 300a, the attenuated laser beam 300b, the concentrated laser beam 300c and the laser beam portions 300d and 300e have a circular shaped cross-section.

The light shape transformers 650 and 650′ transform the laser beam portions 300d and 300e to elliptical shapes or rectangular shapes using concave lenses or convex lenses, respectively. In this embodiment, the light shape transformers 650 and 650′ transform the laser beam portions 300d and 300e to rectangular shapes that are extended in a predetermined direction. The laser beam portions 300d and 300e that pass through the light shape transformers 650 and 650′ are irradiated on an amorphous silicon thin films 200 and 200′, respectively. Preferably, the cross sectional length of the laser beam portions 300d and 300e that pass through the light shape transformers 650 and 650′ are no less than about 700 mm, and the cross sectional width of the laser beam portions 300d and 300e are no more than about 5 μm.

The light shape transformer 650 and 650′ may include masks for transforming the shapes of the laser beam portions 300d and 300e.

By passing through the light shape transformers 650 and 650′, the shapes of the laser beam portions 300d and 300e are transformed resulting in the laser beams 300 and 300′, which are irradiated on the amorphous silicon thin films 200 and 200′ to transform the amorphous silicon thin films 200 and 200′ to polysilicon thin films 400 and 400′.

The transporting units 660 and 660′ transport the silicon thin films 200 and 200′ or the light shape transformers 550 and 550′ so that the laser beams 300 and 300′ outputted from the light shape transformers 550 and 550′ are transported along the amorphous silicon thin films 200 and 200′ to laterally grow the polysilicon crystals, thereby forming the polysilicon thin film 400 and 400′.

Transportation may be continuous or intermittent. When the laser beams 300 and 300′ are continuously transported, the velocity of the transportation can be adjusted to ensure melting of the amorphous silicon thin film 200 and 200′. When transportation is intermittent, the interval of the transportation of the laser beams 300 and 300′ is about 1 μm to about 10 μm.

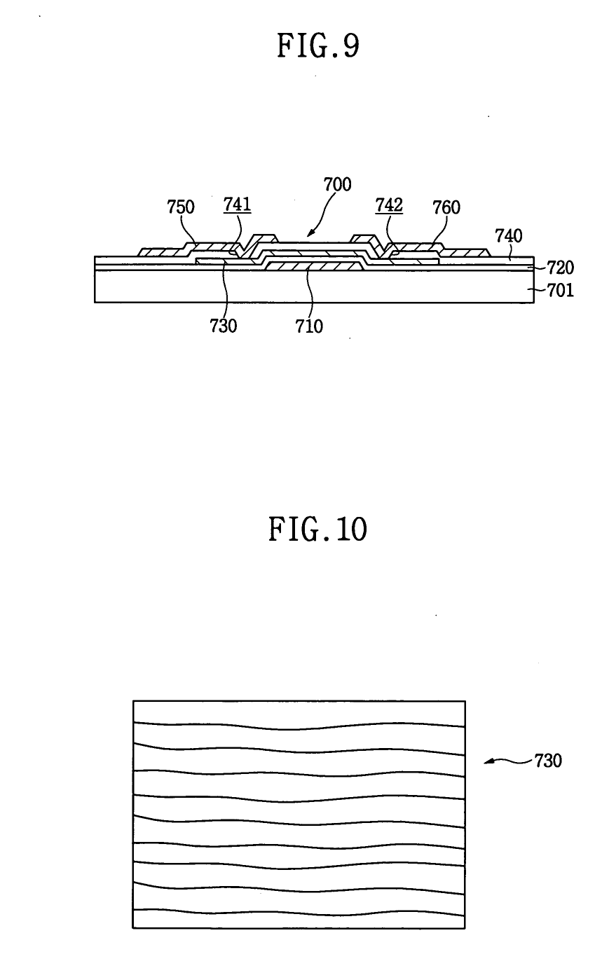

FIG. 9 is a cross-sectional view showing a thin film transistor in accordance with an embodiment of the present invention. FIG. 10 is a plan view showing a polysilicon layer shown in FIG. 9.

Referring to FIGS. 9 and 10, the thin film transistor 700 includes a gate electrode 710, a first insulating layer 720, a polysilicon channel layer 730, a second insulating layer 740, a source electrode 750 and a drain electrode 760.

A gate voltage is provided from an exterior to the gate electrode 710. The gate electrode 710 is formed on a substrate 701.

The first insulating layer 720 is formed over the substrate 701 having the gate electrode 710 thereon to electrically insulate the gate electrode 710.

The polysilicon channel layer 730 is formed on the first insulating layer 720. The polysilicon channel layer 730 is disposed at a position corresponding to the gate electrode 710. The polysilicon channel layer 730 includes a plurality of polysilicon crystals that are parallelly disposed with respect to one another.

The polysilicon channel layer 730 is formed using a laser beam having a pulse frequency that is about 300 Hz to about 4 kHz. A direction of crystal growth of the polysilicon in the polysilicon channel layer 730 is substantially parallel with a transporting direction of the laser beam so that the polysilicon channel layer 730 includes one crystal growth direction. The electrical characteristics of the polysilicon channel layer 730 are better than that of a polysilicon channel layer having a plurality of crystal growth directions or than that of an amorphous silicon channel layer.

The second insulating layer 740 is formed over the first insulating layer 720 having the polysilicon channel layer 730 thereon. The second insulating layer 740 includes a first contact hole 741 and a second contact hole 742. The polysilicon channel layer 730 is exposed through the first and second contact holes 741 and 742.

The source electrode 750 is electrically connected to the polysilicon channel layer 730 through the first contact hole 741. The drain electrode 760 is electrically connected to the polysilicon channel layer 730 through the second contact hole 742.

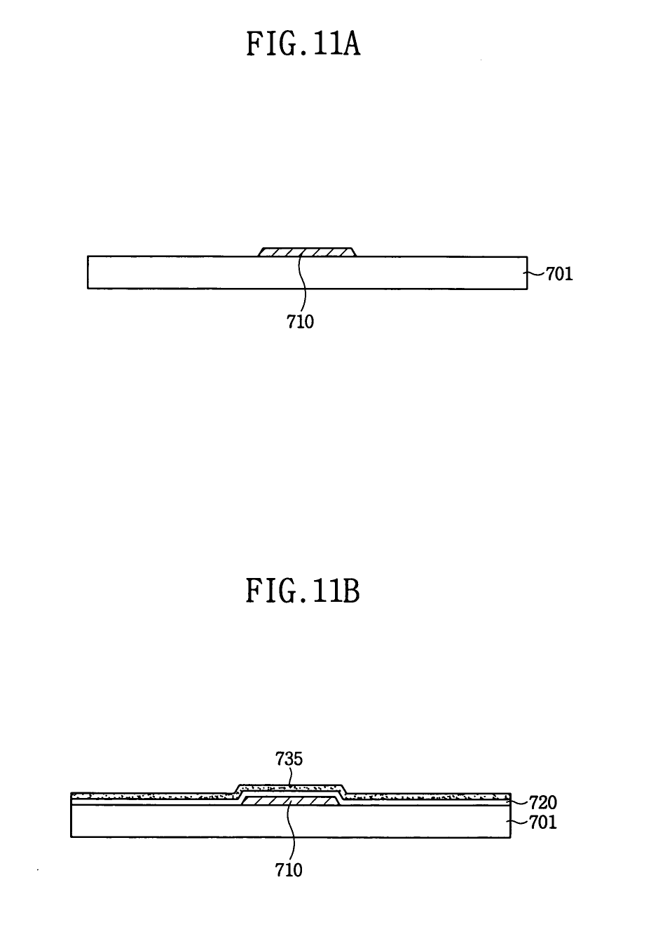

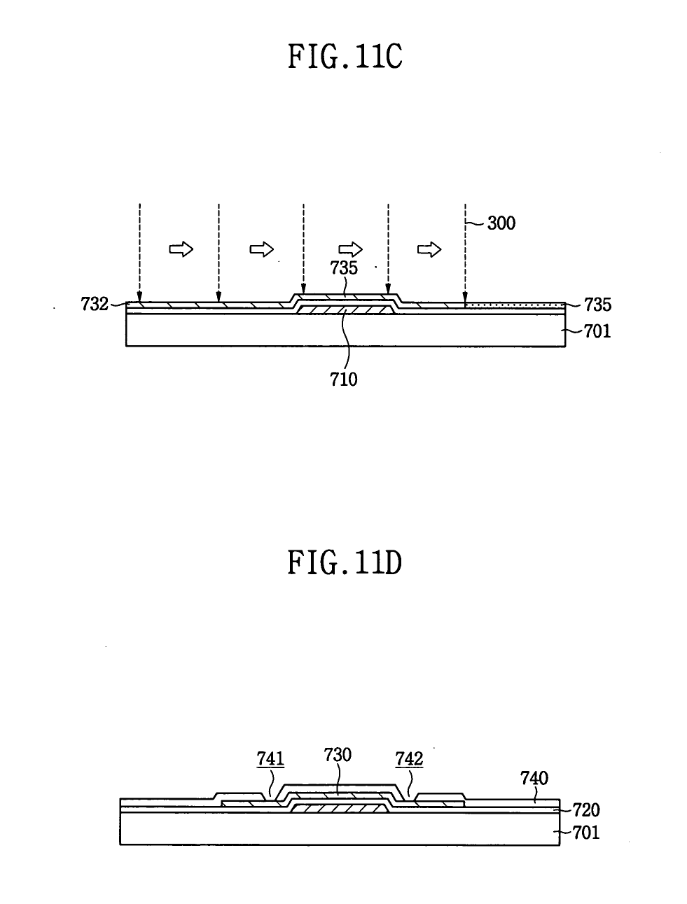

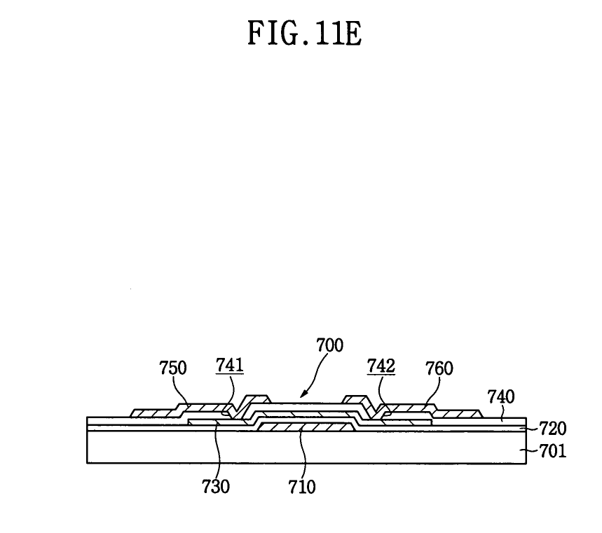

FIGS. 11A to 11E are cross sectional views for illustrating a method of forming a thin film transistor in accordance with an embodiment of the present invention.

Referring to FIG. 11A, a metal is deposited over the substrate 701 to form a gate thin film. The gate thin film is patterned through a photolithography process to form the gate electrode 710 on the substrate 701.

Referring to FIG. 11B, an insulating material is deposited on the substrate 701 having the gate electrode 710 thereon to form the first insulating layer 720.

Amorphous silicon is deposited on the first insulating layer 720 to form an amorphous silicon thin film 735.

Referring to FIG. 11C, a laser beam 300 having a pulse frequency is irradiated on the amorphous silicon thin film 735. The pulse frequency is about 300 Hz to about 4 kHz. The amorphous silicon thin film 735 is then melted and laterally crystallized to form the polysilicon thin film 732.

The polysilicon crystals in the polysilicon thin film 732 are aligned in a predetermined direction.

Referring to FIG. 11D, the polysilicon thin film 732 formed on the first insulating layer 720 is patterned through a photolithography process to form the polysilicon channel layer 730 on the first insulating layer 720. The polysilicon channel layer 730 is disposed at a position corresponding to the gate electrode 710.

An insulating material is deposited on the first insulating layer 720 having the polysilicon channel layer 730 thereon. The deposited insulating material is patterned through a photolithography process to form second insulating layer 740 including the first and second contact holes 741 and 742, through which the polysilicon channel layer 730 is exposed.

Referring to FIG. 11E, a metal is deposited on the second insulating layer 740. The deposited metal is patterned through a photolithography process to form the source electrode 750 and the drain electrode 760.

The source electrode 750 is electrically connected to the polysilicon channel layer 730 through the first contact hole 741. The drain electrode 760 is electrically connected to the polysilicon channel layer 730 through the second contact hole 742.

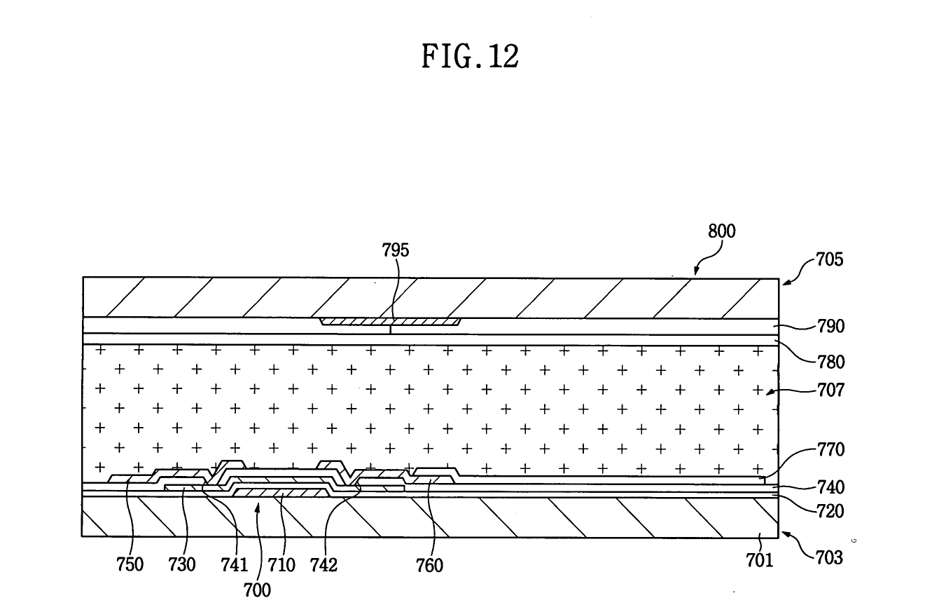

FIG. 12 is a cross sectional view showing a display apparatus in accordance with an embodiment of the present invention.

Referring to FIG. 12, the display apparatus 800 includes a first substrate 703, a second substrate 705 and a liquid crystal layer 707.

The first substrate 703 includes a plurality of thin film transistors 700 and a plurality of pixel electrodes 770 that are arranged in a matrix shape.

Each of the thin film transistors 700 includes a gate electrode 710, a first insulating layer 720, a polysilicon channel layer 730, a second insulating layer 740, a source electrode 750 and a drain electrode 760.

A gate voltage is applied to the gate electrode 710 from an exterior. The gate electrode is formed on the substrate 701.

The first insulating layer 720 is formed on the substrate 701 having the gate electrode 710 formed thereon. The first insulating layer 720 electrically insulates the gate electrode 710.

The polysilicon channel layer 730 is formed on the first insulating layer 720. The polysilicon channel layer 730 is disposed at a position corresponding to the gate electrode 710. The polysilicon channel layer 730 includes a plurality of polysilicon crystals that are parallelly disposed in a predetermined direction.

The polysilicon crystals are formed using a laser beam. The pulse frequency of the laser beam is about 300 Hz to about 4 kHz. A crystal growth direction of the polysilicon crystals is substantially parallel with a transporting direction of the laser beam so that the polysilicon channel layer 730 includes one crystal growth direction. The electrical characteristics of the polysilicon channel layer 730 are better than that of a polysilicon channel layer having a plurality of crystal growth directions or than that of an amorphous silicon channel layer.

The second insulating layer 740 is disposed on the first insulating layer 720 having the polysilicon channel layer 730 thereon. The second insulating layer 740 includes a first contact hole 741 and a second contact hole 742, through which the polysilicon channel layer 730 is exposed.

The source electrode 750 is electrically connected to the polysilicon channel layer 730 through the first contact hole 741. The drain electrode 760 is electrically connected to the polysilicon channel layer 730 through the second contact hole 742.

Each of the pixel electrodes 770 includes a transparent conductive material such as indium tin oxide (ITO), indium zinc oxide (IZO), zinc oxide (ZO), etc. The pixel electrode 770 is electrically connected to the drain electrode 760 of the thin film transistor 700.

The second substrate 705 faces the first substrate 703. A common electrode 780 is formed on a surface of the second substrate 705, which corresponds the first substrate 703. The common electrode 780 is formed over the second substrate 705. The common electrode 780 includes indium tin oxide (ITO), indium zinc oxide (IZO), zinc oxide (ZO), etc.

A color filter 790 may be disposed between the second substrate 705 and the common electrode 780. A plurality of the color filters 790 may be disposed at positions corresponding to the pixel electrodes 770 disposed on the first substrate 703.

A black matrix 795 is formed on the second substrate 705 to block light that passes through a space between the color filters 790. A plurality of the black matrixes 795 may be formed on the second substrate 705.

According to embodiments of the present invention, a laser beam having decreased output energy is irradiated on the amorphous silicon thin film to crystallize the amorphous silicon thin film to a polysilicon thin film. Therefore, the load of an apparatus for generating the laser beam is decreased, and the lifetime of the apparatus for generating the laser beam increases. In addition, the characteristics of the thin film transistor and the display quality of the display apparatus are improved.

Although the illustrative embodiments have been described herein with reference to the accompanying drawings, it is to be understood that the present invention is not limited to those precise embodiments, and that various other changes and modifications may be affected therein by one of ordinary skill in the related art without departing from the spirit or scope of the invention. All such changes and modifications are intended to be included within the scope of the invention as defined by the appended claims.

1. A method of crystallizing silicon, comprising:
generating light having a pulse frequency higher than about 300 Hz;
irradiating the light on at least one amorphous silicon thin film for a predetermined time period to form an initial polysilicon crystal; and
transporting the light in a predetermined direction to grow the initial polysilicon crystal.

2. The method as recited in claim 1, wherein the pulse frequency is in the range of about 300 Hz to about 4 KHz.

3. The method as recited in claim 1, wherein the pulse frequency is higher than about 4 KHz.

4. The method as recited in claim 1, wherein the light has a rectangular shape.

5. The method as recited in claim 1, wherein the step of transporting the light occurs continuously or intermittently.

6. The method as recited in claim 5, further comprising adjusting the velocity of transportation when the light is continuously transported.

7. The method as recited in claim 5, wherein an interval of transportation of the light is about 1 μm to about 10 μm when the light is intermittently transported.

8. The method as recited in claim 1, wherein the light has an output energy in the range of about 100 mJ to about 1 J.

9. A method of crystallizing silicon, comprising:
generating light having a pulse frequency higher than about 300 Hz;
dividing the light into a plurality of light portions;
irradiating each of the plurality of light portions on a respective amorphous silicon thin film of a plurality of amorphous silicon thin films for a predetermined time period to form a plurality of initial polysilicon crystals; and
transporting each of the plurality of light portions in a predetermined direction to grow the plurality of initial polysilicon crystals.

10. The method as recited in claim 9, wherein each of the plurality of light portions has the pulse frequency higher than about 300 Hz.

11. The method as recited in claim 9, wherein the pulse frequency is in the range of about 300 Hz to about 4 KHz.

12. The method as recited in claim 9, wherein the pulse frequency is higher than about 4 KHz.

13. The method as recited in claim 9, wherein each of the plurality of light portions has a rectangular shape.

14. The method as recited in claim 9, wherein the step of transporting each of the plurality of light portions occurs continuously or intermittently.

15. The method as recited in claim 14, further comprising adjusting the velocity of transportation when each of the plurality of light portions is continuously transported.

16. The method as recited in claim 14, wherein an interval of transportation of each of the plurality of light portions is about 1 μm to about 10 μm when each of the plurality of light portions is intermittently transported.

17. The method as recited in claim 9, wherein the light has an output energy in the range of about 100 mJ to about 1 J.

18. The method as recited in claim 9, wherein each of the plurality of light portions has an output energy less than the output energy of the light.

19. An apparatus for crystallizing silicon, comprising:
an attenuator positioned to receive a primary beam having a pulse frequency higher than about 300 Hz from a light source and for generating an attenuated beam;
a concentrator for concentrating the attenuated beam and generating a concentrated beam; and
a light shape transformer for transforming a shape of the concentrated beam and generating a transformed beam, wherein the transformed beam is irradiated on an amorphous silicon thin film to form a polysilicon thin film.

20. The apparatus as recited in claim 19, wherein the pulse frequency is in the range of about 300 Hz to about 4 KHz.

21. The apparatus as recited in claim 19, wherein the pulse frequency is higher than about 4 KHz.

22. The apparatus as recited in claim 19, further comprising a transporting unit for transporting one of the amorphous silicon thin film or the light shape transformer so that the transformed beam is transported along the amorphous silicon thin film to grow polysilicon crystal.

23. The apparatus as recited in claim 19, further comprising a mirror for changing a direction of the attenuated beam.

24. The apparatus as recited in claim 19, further comprising a mirror for changing a direction of the concentrated beam.

25. The apparatus as recited in claim 19, wherein a cross-section of each of the primary beam, the attenuated beam and the concentrated beam is a circular shape.

26. The apparatus as recited in claim 19, wherein the shape of the concentrated beam is transformed into an elliptical shape or a rectangular shape.

27. The apparatus as recited in claim 19, wherein a cross-sectional length of the concentrated beam is not less than about 700 mm.

28. The apparatus as recited in claim 19, wherein the cross-sectional width of the concentrated beam is not more than about 5 μm.

29. An apparatus for crystallizing silicon, comprising:
a light source for generating a primary beam having a pulse frequency higher than about 300 Hz;
an attenuator positioned adjacent to the light source for generating an attenuated beam;
a concentrator positioned adjacent to the attenuator for concentrating the attenuated beam and generating a concentrated beam;
a beam divider positioned adjacent to the concentrator for dividing the concentrated beam into at least two beams; and
at least two light shape transformers positioned adjacent to the beam divider for respectively transforming a shape of each of the at least two beams and generating at least two respective transformed beams, wherein the at least two respective transformed beams are respectively irradiated on at least two amorphous silicon thin films to form at least two polysilicon thin films.

30. The apparatus as recited in claim 29, wherein the pulse frequency is in the range of about 300 Hz to about 4 KHz.

31. The apparatus as recited in claim 29, wherein the pulse frequency is higher than about 4 KHz.

32. The apparatus as recited in claim 29, wherein a cross-section of each of the primary beam, the attenuated beam, the concentrated beam and the at least two beams is a circular shape.

33. The apparatus as recited in claim 29, wherein the shape of each of the at least two beams is transformed into an elliptical shape or a rectangular shape.

34. The apparatus as recited in claim 29, wherein the beam divider includes a plurality of dividing lenses disposed one of parallelly, serially and in a matrix shape.

35. A method of forming a thin film transistor, comprising:
forming a gate electrode on a substrate;
forming a first insulating layer on the substrate having the gate electrode formed thereon;
forming an amorphous silicon thin film on the first insulating layer;
irradiating light having a pulse frequency in the range of about 300 Hz to about 4 kHz on the amorphous silicon thin film;
transporting the light in a predetermined direction to grow polysilicon crystals to form a polysilicon thin film; and
patterning the polysilicon thin film to form a polysilicon layer on the first insulating layer.

36. The method as recited in claim 35, further comprising forming a second insulating layer on the first insulating including the polysilicon layer, wherein the second insulating includes a first contact hole and a second contact hole exposing the polysilicon layer.

37. The method as recited in claim 35, further comprising forming a source electrode and a drain electrode on the second insulating layer corresponding to the first and second contact holes, wherein the source electrode is electrically connected to the polysilicon layer through the first contact hole and the drain electrode is electrically connected to the polysilicon layer through the second contact hole.

38. A thin film transistor comprising:
a gate electrode formed on a substrate;
a first insulating layer formed on the substrate including the gate electrode formed thereon; and
a channel layer disposed on the first insulating layer, wherein the channel layer includes a plurality of polysilicon crystals arranged in a predetermined crystal growth direction.

39. The thin film transistor as recited in claim 38, further comprising:
a second insulating layer disposed on the channel layer including a first contact hole and a second contact hole; and
a source electrode and a drain electrode formed on the second insulating layer, wherein the source electrode is electrically connected to the channel layer through the first contact hole and the drain electrode is electrically connected to the channel layer through the second contact hole.

40. The thin film transistor as recited in claim 38, wherein the plurality of polysilicon crystals are parallelly disposed with respect to each other.

41. The thin film transistor as recited in claim 38, wherein the predetermined crystal growth direction is substantially parallel to a transporting direction of a laser beam for forming the plurality of polysilicon crystals.

42. The thin film transistor as recited in claim 41, wherein the laser beam has a pulse frequency in the range of about 300 Hz to about 4 KHz.

43. A liquid crystal display apparatus including the thin film transistor as recited in claim 38.

44. A display apparatus, comprising:
a first substrate including a thin film transistor and a pixel electrode; and
a second substrate including a common electrode, wherein a liquid crystal layer is capable of being interposed between the first and second substrates, and the thin film transistor includes:
a gate electrode formed on a transparent substrate;
a first insulating layer formed on the transparent substrate including the gate electrode formed thereon; and
a channel layer disposed on the first insulating layer, wherein the channel layer includes a plurality of polysilicon crystals arranged in a predetermined crystal growth direction.

45. The display apparatus as recited in claim 44, wherein the plurality of polysilicon crystals are parallelly disposed with respect to each other.

46. The display apparatus as recited in claim 44, wherein the predetermined crystal growth direction is substantially parallel to with a transporting direction of a laser beam for forming the plurality of polysilicon crystals.

47. The display apparatus as recited in claim 46, wherein the laser beam has a pulse frequency in the range of about 300 Hz to about 4 KHz.
